(19) United States
(12) Patent Application Publication
(10) Pub. No.: US 2012/0211884 A1
(43) Pub. Date: Aug. 23, 2012

(54) WAFER CHIP SCALE PACKAGE CONNECTION SCHEME

(76) Inventors: Frank Stepniak, Allen, TX (US); Christopher Daniel Manack, Lewisville, TX (US); Licheng M. Han, Frisco, TX (US)

(21) Appl. No.: 13/033,064

(22) Filed: Feb. 23, 2011

(51) Int. Cl. H01L 23/485; H01L 21/441

(52) U.S. Cl. 257/737; 438/614; 257/E23.021; 257/E21.477

(57) ABSTRACT

A method and structure for forming a semiconductor device, for example a device including a wafer chip scale package (WCSP), can include the formation of at least one conductive layer which contacts a bond pad. The at least one conductive layer can be patterned using a first mask, then a passivation layer can be formed over the patterned at least one conductive layer. The passivation layer can be patterned using a second mask to expose the at least one conductive layer, then a conductive layer such as a solder ball, conductive bump, metal-filled paste, or another conductor is formed on the at least one conductive layer. The method can result in a structure which is formed using a reduced number of mask steps.

### FIELD OF THE INVENTION

The present teachings relate to the field of semiconductor devices, and more specifically to semiconductor dies and wafer chip scale packages (WCSPs).

### BACKGROUND OF THE INVENTION

Miniaturization of semiconductor device packages and electronic components is an ongoing goal for design engineers. Reducing a package “footprint” results in the increased availability of space on a receiving surface to which the package is mounted, such as a printed circuit board (PCB), thereby increasing the density of devices that can be attached to the receiving surface. Increasing device density is one strategy for decreasing the size of an electronic device.

A surface mount semiconductor device package includes a semiconductor die encased in a resin encapsulation material. Electrical communication with the encapsulated die can be provided through lead frame leads or a ball grid array.

To further reduce the package footprint, other device packages have been developed. For example, a wafer chip scale package (WCSP) eliminates device encapsulation altogether, and provides an unencapsulated (i.e. “bare”) die that can be mounted onto the receiving surface. This package has a very small outline that can equal the size of the die itself.

During the manufacture of WCSP devices in wafer form, a plurality of semiconductor dies (i.e. chips) are formed en masse on and within a semiconductor substrate, then the wafer is diced using a laser and/or a dicing saw. To provide electrical communication between active circuitry formed on and within the WCSP die and the receiving substrate, a number of patterned electrically conductive layers and insulation layers can be provided using a number of different mask steps.

FIG. 1 depicts a structure including a WCSP semiconductor die. The WCSP semiconductor die can include a semiconductor substrate 10 having active circuitry 12 formed over, on, and/or within the semiconductor substrate 10, and a conductive pad 14 such as a bond pad which is electrically coupled with the active circuitry 12. After providing the WCSP semiconductor die, a first passivation layer 16 can be patterned to provide an opening which exposes the conductive pad 14. A conductive layer 18, typically referred to as a redistribution layer or “RDL,” can be formed and patterned to electrically couple with the bond pad 14 and extends over the surface of the semiconductor substrate 10 to a selected location where external electrical contact to the active layer 12 will be provided.

A second passivation layer 20 can be patterned to provide an opening which exposes the RDL 18 at the selected location. Another conductive layer 22, typically referred to as under bump metallization or “UBM,” can be formed and patterned to electrically couple with the RDL 18. The UBM 22 protects the exposed edges of the second passivation layer 20 to prevent encroachment of a subsequently formed conductive layer 24, such as a solder ball, under the second passivation layer 20. This encroachment could lift the second passivation layer 20 from the RDL 18 and provide a path for contamination as well as short adjacent isolated conductive layers together. The UBM 22 can also provide a diffusion barrier to prevent the diffusion of the conductive layer 24 through the material of the RDL 18, which could also short adjacent isolated conductive layers together.

Thus after forming the conductive pad 14 and the patterned first passivation layer 16, the RDL 18 is patterned with a first patterned mask, the second passivation layer 20 is patterned with a second patterned mask, and the UBM 22 is patterned with a third patterned mask.

U.S. Pat. No. 6,683,380, assigned to Texas Instruments and incorporated herein by reference, can include the use of a patterned conductive layer which contacts a die pad.

### SUMMARY OF THE EMBODIMENTS

In contemplating the current state of the art, the inventors have realized that the formation of a WCSP structure includes the use of several photolithography masks, which increases the cost of device manufacture. Each mask used to pattern a layer is expensive. Further, each mask step requires the application of a photoresist (resist), proper alignment of the mask with the semiconductor die, exposure of the resist to a light source using the mask as a pattern, developing of the resist to result in the pattern within the resist, an etch of a layer underlying the patterned resist, and removal of the resist after patterning the underlying layer.

The inventors have discovered that some implementations of a WCSP device can be formed using a reduced number of steps and a reduced number of masks. During testing of the properties of a passivation layer, specifically a polyimide passivation layer, the inventors have discovered that polyimide adheres sufficiently to a metal layer, for example a copper layer or a palladium layer, such that the formation of a separate under bump metallization can be omitted in some structures. This is particularly true when a material selected as a redistribution layer also provides sufficient functionality as a diffusion barrier. This functionality can be realized, for example, when a metal redistribution layer is formed from a metal which sufficiently resists diffusion from an overlying layer, thus providing functionality as a UBM. Thus a single metal layer can function as both a redistribution layer a UBM, alleviating the need for separate layers formed by separate patterned masks to provide this functionality.

Thus the inventors have developed a simplified method for forming a WCSP structure which requires fewer mask steps, requires less processing time, and is therefore less expensive than previous WCSP methods.

### BRIEF DESCRIPTION OF THE DRAWINGS

The accompanying drawings, which are incorporated in and constitute a part of this specification, illustrate embodiments of the present teachings and together with the description, serve to explain the principles of the disclosure in the figures:

FIG. 1 is a cross section of a conventional WCSP device;

FIGS. 2-7 are cross sections of intermediate structures of an in-process device in accordance with an embodiment of the present teachings;

FIG. 8 is a cross section of an embodiment including a WCSP semiconductor device attached to a receiving substrate;

FIG. 9 is a cross section depicting another embodiment according to the present teachings;

FIG. 10 is a cross section depicting another embodiment of the present teachings; and

FIG. 11 is a cross section depicting another embodiment of the present teachings.

It should be noted that some details of the FIGS. have been simplified and are drawn to facilitate understanding of the inventive embodiments rather than to maintain strict structural accuracy, detail, and scale.

### DESCRIPTION OF THE EMBODIMENTS

Reference will now be made in detail to the present exemplary embodiments of the present teachings, example of which are illustrated in the accompanying drawings. Wherever possible, the same reference numbers will be used throughout the drawings to refer to the same or like parts.

Intermediate structures formed during an embodiment the present teachings are depicted in the cross sections of FIGS. 2-7. A method and structure according to the present teachings can include a semiconductor device such as a wafer chip scale package (WCSP).

FIG. 2 depicts a structure including a semiconductor substrate 100 which can be part of a semiconductor wafer or wafer section. The semiconductor substrate 100 can be a silicon substrate, a gallium arsenide substrate, or another material which is sufficient to manufacture a semiconductor device. The semiconductor substrate 100 can have various layers formed over, on, and/or within the substrate 100, which forms active circuitry 112. Active circuitry 112 can include, for example, one or more conductive layers having intervening dielectric layers and passivation layers. The FIG. 2 structure can further include a conductive pad 116 such as an aluminum bond pad, and a first passivation layer 114 having an opening 118 therein which exposes the bond pad 116. The first passivation layer 114 can include, for example, a polyimide layer or another dielectric layer. The bond pad is electrically coupled with the active circuitry 112, for example through contact with a conductive layer. The structure of FIG. 2 can be formed using techniques known in the art.

Subsequently, a blanket conductive layer 120 and a first patterned mask layer 122 are formed over the FIG. 2 structure to result in a structure similar to that depicted in FIG. 3. The blanket conductive layer 120 can be a single layer of copper. The blanket conductive layer 120 can function as a redistribution layer (RDL) to reroute a signal, such as a data signal, power, ground, etc., from the location of the bond pad 116 to another point over the active circuitry 112. In an embodiment, the blanket conductive layer can have a thickness of between about 4.0 μm and about 8.0 μm, for example about 6 μm. This thickness may provide a layer which is sufficient to resist excessive metal loss during operation of the device and can provide a low-resistance connection. If this layer is excessively thick, a subsequent polyimide may not re-passivate the top of the metal stack.

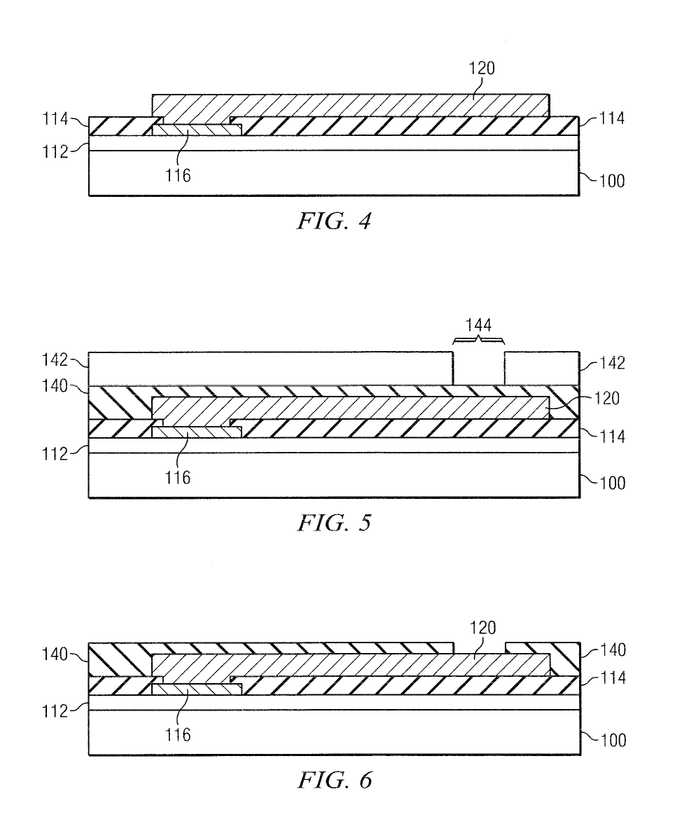

Next, an etch of the FIG. 3 structure is performed to remove exposed portions of the blanket conductive layer 120 and to stop on the first passivation layer 114. The first patterned mask layer 122 is then removed to result in a structure similar to that depicted in FIG. 4, in which the blanket conductive layer 120 is etched to result in a patterned conductive layer 120.

After forming the FIG. 4 structure, a second passivation layer 140 and a second patterned mask 142 are formed as depicted in FIG. 5. The second passivation layer 140 can include a polyimide coating having a thickness of between about 8.0 μm and about 12.0 μm, for example about 10.0 μm. This thickness of the passivation layer is sufficient to resist the underflow of a subsequent conductive layer and to protect the upper surface of the device. Forming an excessively thick layer will use additional material and increase costs. The second patterned mask 142 has an opening 144 which exposes a portion of the second passivation 140 at a location designed to receive a connection such as a solder ball. The exposed portion of the second passivation layer 140 is etched to expose the conductive layer 120. The second patterned mask 142 is then removed to result in the structure of FIG. 6.

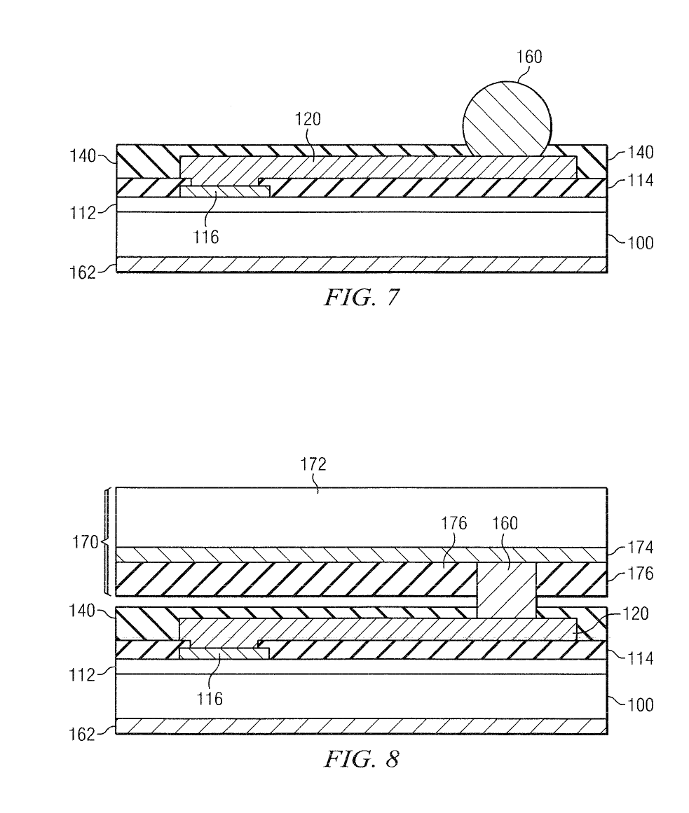

Next, an electrically conductive structure 160 is formed to electrically contact the exposed conductive layer 120 as depicted in FIG. 7. The electrically conductive structure 160 can be a solder ball such as that depicted in FIG. 7, or another conductive structure such as an electrically conductive paste, pillar, bump, stud, etc. The material which forms conductive structure 160 can include, for example, a conductive-filled paste, gold, tin-lead solder, or another conductive material.

The FIG. 7 structure can also include a back side conductive layer such as a back side metal 162. Depending on the types of semiconductor devices, the back side metal 162 can facilitate or improve operation of the device. For example, a back side conductive layer can be used with various transistor devices, such as vertical depletion metal oxide semiconductor (VDMOS) transistor devices.

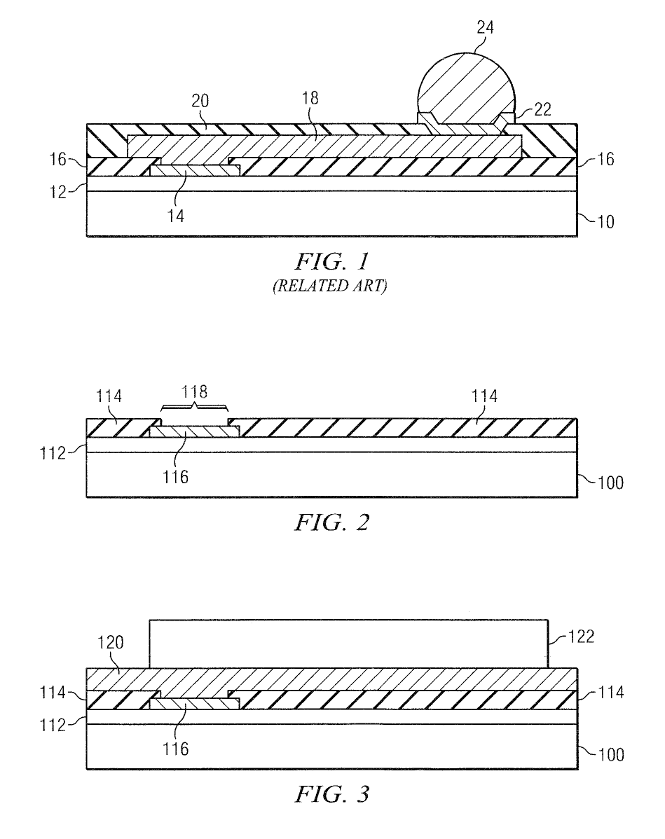

In this embodiment, the second passivation layer 140 has been found to adhere well to a copper conductive layer 120 without additional treatment. The adhesion has been found during testing to be sufficient to reduce or eliminate the flow of metal from conductor 160 under the second passivation layer 140. Because of this good adhesion, a patterned UBM layer 22 as depicted in FIG. 1 can be omitted, which simplifies manufacture, reduces mask processing, eliminates the need for a mask, decreases processing time, and therefore reduces processing costs. In an embodiment to form the FIG. 7 structure, no additional patterned masks are used between the use of the first patterned mask to form the opening 118 in the first passivation layer 114 and the formation of the bump 160, except for the patterned mask 142 which is used to pattern and form the opening in the second dielectric layer 140.

The FIG. 7 device including, for example, a single copper layer 120 is particularly suited for low power devices such as low power static or dynamic random access memories, digital signal processors, logic devices, etc. Such devices typically operate at a voltage of 5.0 volts or less, for example at 3.3 volts or less. The single copper layer 120 is resilient to solder consumption in both low power devices and high power devices. Using a single copper layer 120 simplifies the process in that multiple layers are not required to form the layer.

In another embodiment, the FIG. 7 device can be electrically coupled with a receiving substrate 170 as depicted in FIG. 8. The receiving substrate 170 can include a printed circuit board (PCB), another semiconductor substrate, a ceramic substrate, etc. In the exemplary embodiment depicted, tile receiving substrate 170 can include a supporting substrate 172 such as a resin support, one or more conductor layers 174, and an overlying dielectric layer 176.

To electrically couple the FIG. 7 device with the receiving substrate 170 as depicted in FIG. 8 when the electrically conductive material 160 is a flowable metal such as solder, the FIG. 7 structure is aligned with, and placed in physical contact with, the receiving substrate 170. The flowable metal 160 is heated and flowed such that electrical coupling is established between the conductive layer 120 and the conductor layer 174.

In an alternate embodiment of the FIG. 8 structure when the electrically conductive material 160 is an electrically conductive paste, the conductive paste 160 is formed, placed into physical contact with both the conductive layer 140 and the conductor layer 174, then cured such that the conductive layer 140 is electrically coupled with the conductor layer 174, to result in the structure similar to that depicted in FIG. 8.

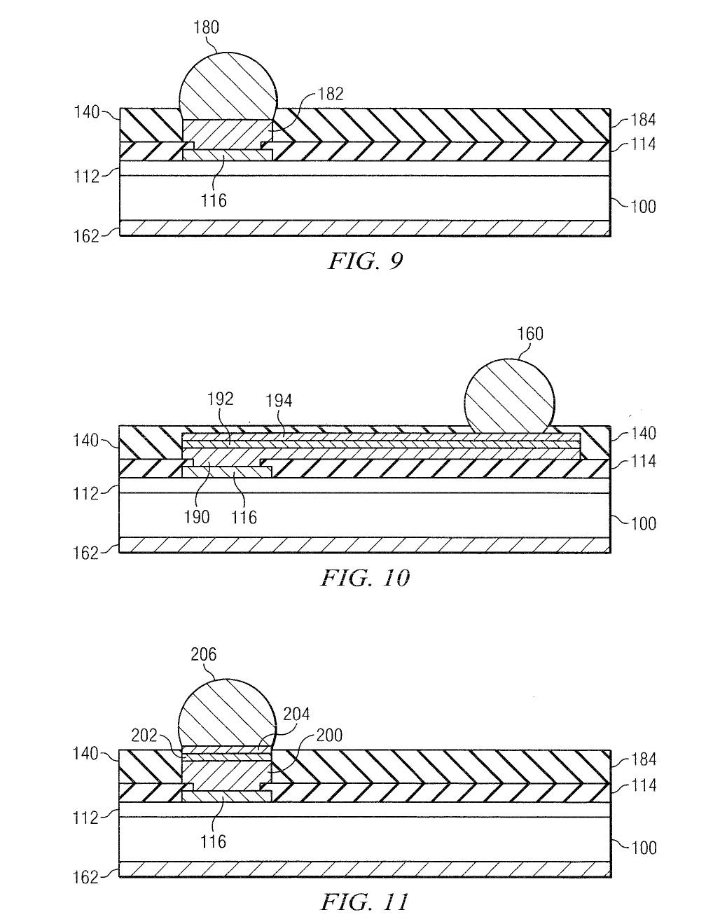

FIG. 9 depicts an embodiment in which a conductive material 180, such as a solder ball or other flowable metal, conductive paste, conductive stud, etc., is formed directly over the conductive pad 116. The conductive layer 182 can be patterned using a first mask such that the conductive layer 182 is localized directly over the conductive pad 116. In this embodiment, the conductive material 180 is not rerouted away from the location of the conductive pad 116. The second passivation layer 184 is patterned such that the conductive layer 182 is exposed through an opening within the second passivation layer 184 at a location directly over the conductive layer 182 and directly over the conductive pad 116. The location of the opening within the second passivation layer 184 directly over the conductive pad 116 facilitates electrical connection (electrical coupling) between the conductive material 182 and the conductive layer 180 at a location directly over the conductive pad 116.

FIG. 10 depicts another embodiment in which the conductive layer includes a first conductive layer of copper 190, a second conductive layer of nickel 192, and a third conductive layer of either copper or palladium 194. The first conductive layer of copper 190 can have a thickness of between about 4.0 μm and about 8.0 μm, for example about 6.0 μm. The second conductive layer of nickel 192 can have a thickness of between about 2.0 μm to about 4.0 μm, for example about 3.0 μm. The third conductive layer of either copper or palladium 194 formed on the nickel 192 can have a thickness of between about 0.2 μm and about 0.4 μm, for example about 0.3 μm. Thus together the first, second, and third conductive layers can have a combined thickness of between about 6.2 μm and about 12.4 μm. After forming the third conductive layer 194, the patterned passivation layer 140 and conductive material 160 can be formed to a sufficient thickness according to previous embodiments described above.

In the case where solder or another flowable metal is used as the conductive material 160, the second conductive layer of nickel 192 can reduce or prevent diffusion of the metal 160 through the first conductive layer 190. While nickel may provide a better diffusion barrier than another material such as palladium, nickel is more prone to the formation of a native oxide. A native oxide between the second conductive layer 192 and the conductive material 160 may increase electrical resistance between the second conductive layer 192 and the conductive material 160. The third conductive layer of either copper or palladium 194 formed on the nickel 192 would provide a nickel layer as a diffusion barrier and an exposed palladium or copper layer, either of which is less prone to the formation of a native oxide than nickel. Thus a second conductive layer of nickel 192 provides a good diffusion barrier while the third conductive layer of copper or palladium 194 reduces or eliminates increased contact resistance which can result from a native oxide.

In addition to resisting a native oxide formation, the third conductive layer of copper or palladium 194 has been found during testing to adhere well to the second passivation layer 140 such that conductive material 160 will not flow under the passivation 140. As such, it has been found that a patterned UBM such as layer 22 in FIG. 1 can be omitted. A UBM 22 typically covers the edge of the second passivation layer 20 and prevents encroachment of metal 24 under the second passivation layer 20, and can also function as a diffusion barrier. In the present teachings, the UBM is omitted and the first copper layer 190 functions as a portion of the RDL, the second layer of nickel 192 functions as a diffusion barrier and a portion of the RDL, and the third layer of copper or palladium 194 functions as a portion of the RDL, as an adherence layer to which the passivation 140 adheres well, and also resists native oxide formation. Each of these layers are patterned using a single patterned mask. Thus manufacturing is simplified, for example because the formation and patterning of the UBM using a different mask than an RDL is not necessary.

The FIG. 10 device including, for example, a copper layer 190, a nickel layer 192, and a copper or palladium layer 194 is suited for high power devices such as AC to DC converters, DC to DC converters, power supplies, etc. Such devices typically include circuit operation at greater than 5.0 volts, for example 30 volts or higher. The multiple metal layers provided by layers 190-194 may be more resilient to solder consumption in high power devices than the device of, for example, FIG. 7.

FIG. 11 depicts another embodiment in which a first conductor layer 200, a second conductor layer 202, and a third conductor layer 204 are formed directly over a bond pad 116. Layers 200-204 can be analogous to layers 190-194 of the FIG. 10 device. That is, layer 200 can include a first layer of copper having a thickness of between about 4.0 μm and about 8.0 μm, for example about 6.0 μm. Layer 202 can include a layer of nickel between about 2.0 μm and about 4.0 μm, for example about 3.0 μm. Layer 204 can include a layer of copper or palladium between about 0.2 μm to about 0.4 μm, for example about 0.3μ. Thus together the first, second, and third conductive layers can have a combined thickness of between about 6.2 μm and about 12.4 μm. Layers 200-204 can be defined at a location directly overlying the bond pad 116 using a mask which results in the depicted pattern and location.

It will be understood that the embodiments of FIGS. 9-11 can be attached to a receiving substrate, for example a receiving substrate 170 similar to that depicted in FIG. 8. It will be further understood that the FIGS. depict only part of the semiconductor die and receiving substrate, and that other structures, to the left or right, or both left and right, of the depicted structures may exist but have been omitted from the depictions. Further, structures above or below the depicted structures may also exist but have been omitted for simplicity of explanation. Additionally, the depicted locations may have other structures such as conductive pads, doped regions, spacers, etc., which have been omitted for simplicity of explanation.

It will be further understood that various patterned conductive layers can be formed by techniques such as masked electroplating, blanket layer formation and patterned etching, sputtering, chemical vapor deposition, plasma vapor deposition, etc. Additionally, device processing can include the use of fluxing, seed layers, reflow, and other techniques which are known in the art and have not been described herein for simplicity.

Notwithstanding that the numerical ranges and parameters setting forth the broad scope of the present teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less than 10” can assume negative values, e.g. −1, —2, −3, −10, −20, −30, etc.

While the present teachings have been illustrated with respect to one or more implementations, alterations and/or modifications can be made to the illustrated examples without departing from the spirit and scope of the appended claims. In addition, while a particular feature of the disclosure may have been described with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the present teachings will be apparent to those skilled in the art from consideration of the specification and practice of the disclosure herein. It is intended that the specification and examples be considered as exemplary only, with a true scope and spirit of the present teachings being indicated by the following claims.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate.

1. A method for forming an electrical connection to a semiconductor die, comprising:
forming a first conductive pad over a semiconductor substrate;
forming a first dielectric layer having an opening therein over the first conductive pad which physically contacts the first conductive pad, wherein the first conductive pad is exposed through the opening in the patterned first dielectric layer;
forming at least one conductive layer, wherein the at least one conductive layer comprises a copper layer which physically and electrically contacts the first conductive pad through the opening in the patterned first dielectric layer and physically contacts the patterned first dielectric layer;
patterning the at least one conductive layer with a first mask;
forming a second dielectric layer over the patterned at least one conductive layer which physically contacts the at least one conductive layer;
patterning the second dielectric layer with a second mask to form an opening within the second dielectric layer to expose a portion of the at least one conductive layer; and
forming a conductive bump which physically contacts the second dielectric layer and which physically and electrically contacts the at least one conductive layer.

2. The method of claim 1 further comprising:
patterning the at least one conductive layer with the first mask to form a second conductive pad located directly over the first conductive pad; and
forming the conductive bump directly over the first conductive pad.

3. The method of claim 1, wherein forming the at least one conductive layer comprises:
forming a first conductive layer comprising copper;
forming a second conductive layer comprising nickel on the first conductive layer;
forming a third conductive layer comprising either copper or palladium on the second conductive layer; and
patterning the first conductive layer, the second conductive layer, and the third conductive layer with the first mask; and
forming the conductive bump on the third conductive layer.

4. The method of claim 3, further comprising:
patterning the first conductive layer, the second conductive layer, and the third conductive layer with the first mask to form a second conductive pad directly over the first conductive pad; and
forming the conductive bump directly over the first conductive pad.

5. The method of claim 3, further comprising:
forming the first conductive layer to a thickness of between about 4.0 μm and about 8.0 82 m;
forming the second conductive layer to a thickness of between about 2.0 μm to about 4.0 μm; and
forming the third conductive layer to a thickness of between about 0.2 μm and about 0.4 μm.

6. The method of claim 3, wherein the semiconductor die is adapted to operate at a voltage of 30 volts or higher.

7. The method of claim 1, further comprising:
forming the at least one conductive layer forms a single conductive layer of copper; and
forming the conductive bump to physically contact the single conductive layer of copper.

8. The method of claim 7, wherein the semiconductor die is adapted to operate at a voltage of 5 volts or less.

9. A method for forming an electrical connection to a semiconductor die, comprising:
forming a first conductive pad over a semiconductor substrate;
forming a first dielectric layer having an opening therein over the first conductive pad which physically contacts the first conductive pad, wherein the first conductive pad is exposed through the opening in the patterned first dielectric layer;
forming a first blanket conductive layer comprising copper which physically and electrically contacts the first conductive pad through the opening in the patterned first dielectric layer and physically contacts the patterned first dielectric layer;
forming a second blanket conductive layer comprising nickel which physically and electrically contacts the first blanket conductive layer;
forming a third blanket conductive layer comprising at least one of copper and palladium which physically and electrically contacts the second blanket conductive layer;
patterning the first blanket conductive layer, the second blanket conductive layer, and the third blanket conductive layer with a first mask;
forming a second dielectric layer over the patterned third blanket conductive layer which physically contacts the patterned third blanket conductive layer;
patterning the second dielectric layer with a second mask to form an opening within the second dielectric layer which exposes at least a portion of the patterned third blanket conductive layer; and
forming a conductive bump which physically contacts the second dielectric layer and which physically and electrically contacts the patterned third blanket conductive layer,
wherein no additional patterned masks are used between the use of the first mask and the formation of the bump except for the patterning of the second dielectric layer.

10. The method of claim 9, further comprising:
forming the first blanket conductive layer from copper; and
forming the second conductive layer from nickel.

11. The method of claim 9, further comprising:
patterning the first blanket conductive layer, the second blanket conductive layer, and the third blanket conductive layer with the first mask to form a second conductive pad directly over the first conductive pad; and
forming the conductive bump directly over the first conductive pad.

12. The method of claim 9, further comprising:
forming the first blanket conductive layer to a thickness of between about 4.0 μm and about 8.0 μm;
forming the second blanket conductive layer to a thickness of between about 2.0 μm to about 4.0 μm; and
forming the third blanket conductive layer to a thickness of between about 0.2 μm and about 0.4 μm.

13. The method of claim 9, wherein the semiconductor die is adapted to operate at a voltage of 30 volts or higher.

14. A semiconductor device, comprising:
a patterned conductive pad;
a first patterned dielectric layer having a first opening therein which exposes the first patterned conductive pad;
a redistribution layer comprising copper which electrically contacts the first patterned conductive pad and physically contacts the first patterned dielectric layer;
a second patterned dielectric layer having a second opening therein which exposes a portion of the redistribution layer and which physically contacts the redistribution layer; and
a conductive bump within the second opening which physically contacts the second patterned dielectric layer and which electrically contacts the redistribution layer.

15. The semiconductor device of claim 14, wherein the redistribution layer comprises a single copper layer.

16. The semiconductor device of claim 15, wherein the conductive bump directly overlies the first patterned conductive pad.

17. The semiconductor device of claim 14, wherein the redistribution layer comprises:
a copper first layer which physically and electrically contacts the first patterned conductive pad;
a nickel second layer which physically and electrically contacts the copper first layer, wherein the nickel layer is adapted to function as a diffusion barrier for the conductive bump; and
a copper or palladium third layer which physically and electrically contacts the nickel second layer and the conductive bump, wherein the third layer is exposed by the second opening in the second patterned dielectric layer.

18. The semiconductor device of claim 17, wherein the conductive bump directly overlies the first patterned conductive pad.
